(19) United States
(12) Patent Application Publication
(10) Pub. No.: US 2026/0148783 A1
(43) Pub. Date: May 28, 2026

(54) SEMICONDUCTOR MEMORY DEVICE AND OPERATING METHOD THEREOF

(71) Applicant: SK hynix Inc., Gyeonggi-do (KR)

(72) Inventor: Nam Cheol JEON, Gyeonggi-do (KR)

(21) Appl. No.: 19/193,989

(22) Filed: Apr. 30, 2025

(30) Foreign Application Priority Data
Nov. 26, 2024 (KR) 10-2024-0170730

(51) Int. Cl. G11C 16/34; G11C 16/04; G11C 16/28; G11C 29/52

(52) U.S. Cl. CPC G11C 16/3495; G11C 16/0483; G11C 16/28; G11C 29/52

(57) ABSTRACT

A semiconductor memory device and a method of operating the semiconductor memory device are provided. The semiconductor memory device includes a memory cell array including a plurality of memory blocks, a peripheral circuit configured to perform a program operation, a read operation, or an erase operation on the plurality of memory blocks, and a control logic configured to set a level of a drain select line operating voltage or a level of a source select line operating voltage corresponding to each memory block based on a number of erase-write (EW) cycles or a number of read operations for each memory block, and control the peripheral circuit to perform the program operation, the read operation, or the erase operation based on the set drain select line operating voltage or the set source select line operating voltage.

### CROSS-REFERENCE TO RELATED APPLICATION

The present application claims priority under 35 U.S.C. § 119(a) to Korean patent application number 10-2024-0170730 filed on Nov. 26, 2024, the entire disclosure of which is incorporated herein by reference.

### BACKGROUND

### 1. Technical Field

Various embodiments of the present disclosure generally relate to an electronic device, and more particularly, to a semiconductor memory device and an operating method of the semiconductor memory device.

### 2. Related Art

A storage device is a device that stores data under the control of a host device such as a computer, a smartphone, or a smart pad. Storage devices include devices that store data on magnetic disks, such as Hard Disk Drives (HDDs), and devices that store data in semiconductor memory, particularly non-volatile memory, such as Solid State Drives (SSDs) and memory cards, depending on the device that stores the data.

The storage device may include a memory device for storing data and a memory controller for controlling the memory device. Memory devices may be a volatile memory or a non-volatile memory. The nonvolatile memory includes Read Only Memory (ROM), Programmable ROM (PROM), Electrically Programmable Rom (EPROM), Electrically Erasable and Programmable Rome (EEPROM), flash memory, Phase-change RAM (PRAM), Magnetic RAM (MRAM), Resistive RAM (RRAM), Ferroelectric RAM (FRAM), or the like.

### SUMMARY

Various embodiments of the present disclosure relate to a semiconductor memory device capable of improving reliability by adjusting an operating voltage by predicting a change in a threshold voltage of a selected transistor and a method of manufacturing the semiconductor memory device.

According to an embodiment of the present disclosure, a semiconductor memory device may include a memory cell array including a plurality of memory blocks, a peripheral circuit configured to perform a program operation, a read operation, or an erase operation on the plurality of memory blocks, and a control logic configured to set a level of a drain select line operating voltage or a level of a source select line operating voltage corresponding to each memory block based on a number of erase-write (EW) cycles or a number of read operations for each memory block, and control the peripheral circuit to perform the program operation, the read operation, or the erase operation based on the set drain select line operating voltage or the set source select line operating voltage.

According to an embodiment of the present disclosure, a method of operating a semiconductor memory device may include receiving a command corresponding to a selected memory block among a plurality of memory blocks, checking a number of erase-write (EW) cycles or a number of read operations of the selected memory block, setting a drain select line operating voltage or a source select line operating voltage of the selected memory block based on the number of EW cycles or the number of read operations of the selected memory blocks, and performing a program operation, a read operation, or an erase operation corresponding to the command by using the set drain select line operating voltage or source select line operating voltage.

According to an embodiment of the present disclosure, a semiconductor memory device may include a memory cell array including a plurality of memory blocks, a peripheral circuit configured to perform a program operation, a read operation, an erase operation, or a select transistor monitoring operation on the plurality of memory blocks, and a control logic configured to control the peripheral circuit to periodically perform the select transistor monitoring operation on each memory block, and set a level of a drain select line operating voltage or a level of a source select line operating voltage used for the program operation, the read operation, or the erase operation based on a number of failure bits corresponding to each memory block, obtained as a result of the select transistor monitoring operation.

According to an embodiment of the present disclosure, a method of operating a semiconductor memory device may include performing a first select transistor monitoring operation on a selected memory block among a plurality of memory blocks, detecting, based on a result of the first select transistor monitoring operation, a number of select transistors having a threshold voltage greater than a first monitoring read voltage among drain select transistors and source select transistors included in the selected memory block to count a first number of failure bits, and setting a drain select line operating voltage or a source select line operating voltage corresponding to the selected memory block based on the counted first number of failure bits.

### BRIEF DESCRIPTION OF THE DRAWINGS

FIG. 1 is a diagram illustrating a data processing system including a semiconductor memory device according to an embodiment of the present disclosure;

FIG. 2 is a diagram illustrating a semiconductor memory device according to an embodiment of the present disclosure;

FIG. 3 is a diagram illustrating an embodiment of a control logic of FIG. 2;

FIG. 4 is a diagram illustrating a memory block of FIG. 2;

FIG. 5 is a diagram illustrating an embodiment of a three-dimensional memory block;

FIG. 6 is a flowchart illustrating a method of operating a semiconductor memory device according to an embodiment of the present disclosure;

FIG. 7 is a diagram illustrating a method of setting a drain select line operating voltage or a source select line operating voltage based on the number of EW cycles or the number of read operations according to an embodiment of the present disclosure;

FIG. 8 is a diagram illustrating another embodiment of the control logic of FIG. 2;

FIG. 9 is a flowchart illustrating a method of operating a semiconductor memory device according to another embodiment of the present disclosure;

FIG. 10 is a threshold voltage distribution diagram for illustrating a select transistor monitoring operation method according to an embodiment of the present disclosure;

FIG. 11 is a diagram illustrating a method of setting a drain select line operating voltage or a source select line operating voltage based on the number of failure bits according to an embodiment of the present disclosure;

FIG. 12 is a threshold voltage distribution diagram illustrating another select transistor monitoring operation method according to an embodiment of the present disclosure;

FIG. 13 is a diagram illustrating a method of setting a drain select line operating voltage or a source select line operating voltage based on the number of failure bits according to an embodiment of the present disclosure; and

FIG. 14 is a block diagram illustrating a configuration of a storage device according to another embodiment of the present disclosure.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Hereinafter, embodiments of the present disclosure will be described in detail with reference to the accompanying drawings in order for those skilled in the art to be able to implement the technical spirit of the present disclosure.

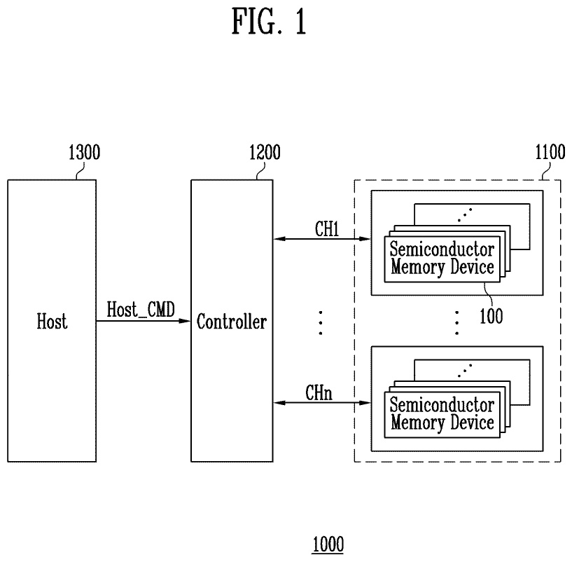

FIG. 1 is a block diagram illustrating a data processing system 1000 including a semiconductor memory device 100 according to an embodiment of the present disclosure.

Referring to FIG. 1, the data processing system 1000 may include a host 1300 and a storage device. The storage device may include a memory device 1100 and a controller 1200. The memory device 1100 may include a plurality of semiconductor memory devices 100. The semiconductor memory devices 100 may be grouped into n memory device groups, where n is a natural number greater than 1. According to an embodiment, the controller 1200, the memory device 1100, and the host 1300 may be configured as one apparatus or separate apparatuses.

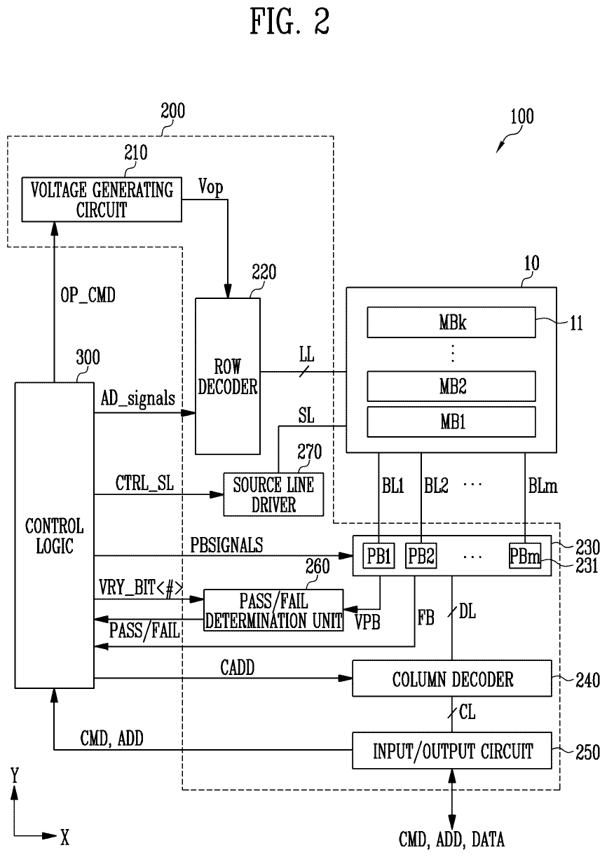

In FIG. 1, the n memory device groups are illustrated as communicating with controller 1200 via first to nth channels CH1 to CHn, respectively. Each semiconductor memory device 100 will be described later with reference to FIG. 2.

Each of the n memory device groups is configured to communicate with the controller 1200 via one common channel. The controller 1200 is configured to control the semiconductor memory devices 100 of the memory device 1100 through the channels CH1 to CHn.

The controller 1200 is coupled between the host 1300 and the memory device 1100. The controller 1200 is configured to access the memory device 1100 according to a request from the host 1300. For example, the controller 1200 is configured to control read, write, erase, and background operations of the memory device 1100 in response to a host command Host_CMD received from the host 1300. In the write operation, the host 1300 may transmit data and an address together with the host command Host_CMD, and in the read operation, may transmit an address together with a host command Host_CMD. The controller 1200 is configured to provide an interface between the memory device 1100 and the host 1300. The controller 1200 is configured to drive firmware for controlling the memory device 1100.

The host 1300 may include a portable electronic device such as a computer, a PDA, a PMP, an MP3 player, a camera, a camcorder, a mobile phone, or the like. The host 1300 may request a write operation, a read operation, an erase operation, or the like to the storage device using the host command Host_CMD. The host 1300 may transmit the host command Host_CMD, data, and address corresponding to the write command to the controller 1200 for the write operation of the memory device 1100, and may transmit the host Command Host_CMD and address corresponding to a read command to the controller 1200 for the read operation. The address may be a logical address.

The controller 1200 and the memory device 1100 may be integrated into one semiconductor device. In an embodiment, the controller 1200 and the memory device 1100 may be integrated into one semiconductor device to form a memory card. For example, the controller 1200 and the memory device 1100 may be integrated into one semiconductor device to form memory cards such as PC cards (PCMCIA, personal computer memory card international association), compact flash cards (CF), smart media cards (SM, SMC), memory sticks, multimedia cards (MMC, RS-MMC, MMCmicro), SD cards (SD, miniSD, microSD, SDHC), and universal flash memory devices (UFS).

The controller 1200 and the memory device 1100 may be integrated into one semiconductor device to form a semiconductor drive (SSD). The semiconductor drive SSD may include the semiconductor memory devices 100 configured to store data therein.

In another embodiment, the data processing system 1000 may be provided as one of various components of an electronic device, such as a computer, a UMPC (Ultra Mobile PC), a workstation, a net-book, a PDA (Personal Digital Assistants), a portable computer, a web tablet, a wireless phone, a mobile phone, a smartphone, an e-book, a PMP (portable multimedia player), a portable game console, a navigation device, a black box, a digital camera, a three-dimensional television, a digital audio recorder, a digital audio player, a digital picture recorder, a digitized picture player, a digitized video recorder, a digitized video player, a device capable of transmitting and receiving information in a wireless environment, one of various electronic devices that make up a home network, one of the various electronic devices that constitute a computer network, one of various electrical devices that constitute a telematics network, an RFID device, or one of the various components that constitute a computing system.

In an embodiment, the storage device or the memory device 1100 may be implemented in various forms of packages. For example, the storage device or the memory device 1100 may be packaged and mounted in a manner such as PoP (Package on Package), Ball grid arrays (BGAs), Chip scale packages (CSPs), Plastic Leaded Chip Carrier (PLCC), Plastic Dual In Line Package (PDIP), Die in Waffle Pack, Die in Wafer Form, Chip On Board (COB), Ceramic Dual In Line package (CERDIP), Metric Quad Flat Pack (MQFP), Thin Quad Flat pack (TQFP), Small Outline Integrated Circuit (SOIC), Shrink Small Outline Package (SSOP), Thin Small Outline Package (TSOP), System In Package (SIP), Multi Chip Package (MCP), Wafer-level Fabricated Package (WFP), Wafer-Level Processed Stack Package (WSP), or the like.

FIG. 2 is a diagram illustrating the semiconductor memory device 100 according to an embodiment of the present disclosure.

Referring to FIG. 2, the semiconductor memory device 100 may include a memory cell array 10 in which data is stored. The semiconductor memory device 100 may include a peripheral circuit 200 configured to perform a program operation to store data in the memory cell array 10, the read operation to output the stored data, and an erase operation to erase the stored data. The semiconductor memory device 100 may include a control logic 300 that controls the peripheral circuit 200 under the control of a controller 1200 of FIG. 1.

The memory cell array 10 may include memory blocks MB1 to MBk 11, where k is a natural number greater than 1. Local lines LL and bit lines BL1 to BLm, may be coupled to each of the memory blocks MB1 to MBk 11, where m is a natural number greater than 1. For example, the local lines LL may include a first select line, a second select line, and a plurality of word lines arranged between the first and second select lines. In addition, the local lines LL may include dummy lines arranged between the first select line and the word lines, and between the second select line and the words lines. The first select line may be a source select line, and the second select line may be the drain select line. For example, the local lines LL may include word lines, drain select lines, source select lines, and source lines SL. For example, the local lines LL may further include dummy lines. For example, the local lines LL may further include pipe lines. The local lines LL may be coupled to the memory blocks MB1 to MBk 11, respectively, and the bit lines BL1 to BLm may be commonly coupled to the memory blocks MB1 to MBk 11. The memory blocks MB1 to MBk 11 may have a two-dimensional or three-dimensional structure. For example, memory cells may be arranged in a direction parallel to the substrate in the memory blocks 11 having a two-dimensional structure. For example, memory cells may be stacked in a direction perpendicular to the substrate in the memory blocks 11 having a three-dimensional structure.

The peripheral circuit 200 may be configured to perform program, read, and erase operations of the selected memory block 11 under the control of the control logic 300. In addition, the peripheral circuit 200 may be configured to perform a monitoring operation on the drain select transistors and the source select transistors included in the selected memory block 11 under the control of the control logic 300. For example, the peripheral circuit 200 may include a voltage generating circuit 210, a row decoder 220, a page buffer group 230, a column decoder 240, an input/output circuit 250, a pass/fail determination unit 260, and a source line driver 270.

The voltage generating circuit 210 may generate various operating voltages Vop used for monitoring operations for program, read, erase, and select transistors in response to an operating signal OP_CMD. In addition, the voltage generating circuit 210 may generate a drain select line operating voltage for applying to the drain select line and a source select line operating voltage to apply to the source select line of the selected memory block in response to the operating signal OP_CMD. The voltage generating circuit 210 may adjust the levels of the drain select line operating voltage and the source select line operating voltage according to the control of the control logic 300. In addition, the voltage generating circuit 210 may selectively discharge the local lines LL in response to the operating signal OP_CMD.

For example, the voltage generating circuit 210 may generate a program voltage, a verify voltage, a pass voltage, a monitoring read voltage, a drain select line operating voltage, and a source select line operating voltage under the control of the control logic 300.

The row decoder 220 may transmit the operating voltages Vop to the local lines LL coupled to the selected memory block 11 in response to control signals AD_signals. For example, the row decoder 220 may selectively apply operation voltages (e.g., a program voltage, a verification voltage, a pass voltage, a monitoring read voltage, or the like) generated by the voltage generating circuit 210 to word lines among the local lines LL in response to the control signals AD_signals. In addition, the row decoder 220 may apply the drain select line operating voltage and the source select line operating voltage generated by the voltage generating circuit 210 to the drain select line and the source select lines among the local lines LL in response to the control signals AD_signals.

The row decoder 220 may apply the program voltage generated by the voltage generating circuit 210 to a selected word line among the local lines LL in response to the control signals AD_signals during the program voltage application operation, and may apply the pass voltage generated by the voltage generating circuit 210 to the remaining unselected word lines. In addition, the row decoder 220 applies the read voltage generated by the voltage generating circuit 210 to a selected word line among the local lines LL in response to the control signals AD_signals during the read operation, and applies the pass voltage generated by the voltage generating circuit 210 to the remaining unselected word lines. In addition, the row decoder 220 applies the monitoring read voltage generated by the voltage generating circuit 210 to the selected drain select line or the selected source select line among the local lines LL in response to the control signals AD_signals during the monitoring operation on the select transistors, and applies the pass voltage generated by the voltage generating circuit 210 to word lines and the unselected drain select line or the unselected source select line.

The page buffer group 230 may include a plurality of page buffers PB1 to PBm 231 coupled to the bit lines BL1 to BLm. The page buffers PB1 to PBm 231 may operate in response to page buffer control signals PBSIGNALS. For example, the page buffers PB1 to PBm 231 may temporarily store data to be programmed during a program operation, or may sense voltages or currents of the bit lines BL1 to BLm during the read operation, the verify operation, or the monitoring operation on selected transistors. Each of the page buffers PB1 to PBm 231 may detect a failure bit by sensing the voltage or current of the bit lines BL1 to BLm during the monitoring operation on the select transistors, and may output failure bit information FB to the control logic 300.

The column decoder 240 may transfer data between the input/output circuit 250 and the page buffer group 230 in response to a column address CADD. For example, the column decoder 240 may exchange data with the page buffers 231 through data lines DL or exchange data with the input/output circuit 250 through column lines CL.

The input/output circuit 250 may transmit an internal command CMD and an address ADD received from the controller 1200 of FIG. 1 to the control logic 300, or may exchange data DATA with the column decoder 240.

During the read operation, the pass/fail determination unit 260 may generate a reference current in response to an allowable bit VRY_BIT<#>, compare a sensing voltage VPB received from the page buffer group 230 with the reference voltage generated by the reference current, and output a pass signal PASS or a failure signal FAIL.

The source line driver 270 is coupled to a memory cell included in the memory cell array 10 through a source line SL, and may control a voltage applied to the source line SL. The source line driver 270 may receive a source line control signal CTRL_SL from the control logic 300, and may control a source line voltage applied to the source line SL based on the source line control signal CTRL_SL.

The control logic 300 may control the peripheral circuit 200 by outputting the operating signal OP_CMD, the control signals AD_signals, the page buffer control signals PBSIGNALS, and the allowable bit VRY_BIT<#> in response to the internal command CMD and the address ADD. In addition, the control logic 300 may determine whether the verification operation has been passed or failed in response to the pass signal PASS or fail signal FAIL.

In an embodiment, the control logic 300 may count the number of erase-write (EW) cycles or the number of read operations of the selected memory block, and may adjust and may set the level of the drain select line operating voltage or the source select line operating voltage applied to the drain select line or the source select line of the selected memory blocks based on the counted number of EW cycles or the counted number of read operations. For example, the control logic 300 may control the voltage generating circuit 210 to raise and reset the level of the drain select line operating voltage or the source select line operating voltage applied to the drain select line or the source select line of the selected memory block when the counted number of EW cycles or the number of read operations of the selected memory blocks exceeds a set number of times (i.e., a reference number), and to generate the reset drain select line operating voltage or the reset source select line operating voltage during various operations, for example, the program operation, the read operation, or the erase operation, of the selected memory block.

In another embodiment, the control logic 300 may control the peripheral circuit 200 to perform a monitoring operation on the select transistors included in each of the memory blocks MB1 to MBk 11 at regular intervals, may receive the failure bit FB obtained as a result of the monitoring operation on the selected transistors, may count the received failure bit FB, and may adjust and set the level of the drain select line operating voltage or the source select line operating voltage applied to the drain select line or the source select line of the selected memory block based on the counted number of failure bits FB. For example, when the number of failure bits FB obtained as the result of the monitoring operation on the select transistors included in the selected memory block is greater than a set number of bits (i.e., a reference number), the control logic 300 may control the voltage generating circuit 210 to raise and reset the level of the drain select line operating voltage or the source select line operating voltage applied to the drain select line or the source select line of the selected memory block, and may generate the reset drain select line operating voltage or source select line operating voltage during various operations of the selected memory blocks, for example, the program operation, the read operation, or the erase operation.

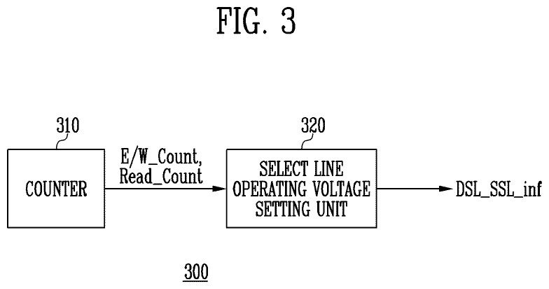

FIG. 3 is a diagram illustrating an embodiment of the control logic 300 of FIG. 2.

Referring to FIG. 3, the control logic 300 may include a counter 310 and a select line operating voltage setting circuit 320.

The counter 310 may count and store the number of EW cycles or the number of read operations of each of the memory blocks MB1 to MBk 11 of FIG. 2. In addition, the counter 310 may output a first count signal E/W_Count or a second count signal Read_Count corresponding to each of the memory blocks MB1 to MBk 11 based on the stored number of EW cycles or the number of read operations. The first count signal E/W_Count may correspond to the counted number of EW cycles of the memory block, and the second count signal Read_Count, may correspond to the calculated number of read operations of the memory block.

The select line operating voltage setting circuit 320 may receive the first count signal E/W_Count or the second count signal Read_Count corresponding to each of the memory blocks MB1 to MBk 11 from the counter 310, and may set the drain select line operating voltage or the source select line operating voltage corresponding to each of memory blocks MB1 and MBk 11 based on the received first count signal E/W_Count and the received second count signal Read_Count.

For example, the select line operating voltage setting circuit 320 may determine the number of EW cycles or the number of read operations of the memory block based on the received first count signal E/W_Count or the received second count signal Read_Count, and may set the drain select line operating voltage or the source select line operating voltage corresponding to the memory block by comparing the determined number of EW cycles or the determined number of read operations with the determined number of setting of the memory block. For example, the select line operating voltage setting circuit 320 may maintain the drain select line operating voltage or the source select line operating voltage at an initial voltage level when it is determined that the number of EW cycles or the number of read operations of the memory block is equal to or less than a first set number, and may set a new drain select line operating power or a new source select line operating power that is increased by a first offset voltage at the initial voltage level when the number of E W cycles or the number of read operations of the memory block exceeds the first set number and is determined to be equal to or less than a second set number that is greater than the first set number. In addition, when it is determined that the number of EW cycles or the number of read operations of the memory block exceeds the second set number, the select line operating voltage setting circuit 320 may set a new drain select line operating voltage or a source select line operating voltage that is increased by a second offset voltage greater than the first offset voltage at the initial voltage level.

The select line operating voltage setting circuit 320 may perform an operation of setting the drain select line operating voltage or the source select line operating voltage for each of the memory blocks MB1 to MBk 11.

The select line operating voltage setting circuit 320 may output select line operating voltage information DSL_SSL_inf including information on the level of the set drain select line operating voltage or the level of the set source select line operating voltage. The select line operating voltage information DSL_SSL_inf may be transmitted to the voltage generating circuit 210 of FIG. 2, and the voltage generating circuit 210 may adjust the levels of the drain select line operating voltage and the source select line operating voltage based on the select line operating voltage information DSL_SSL_inf.

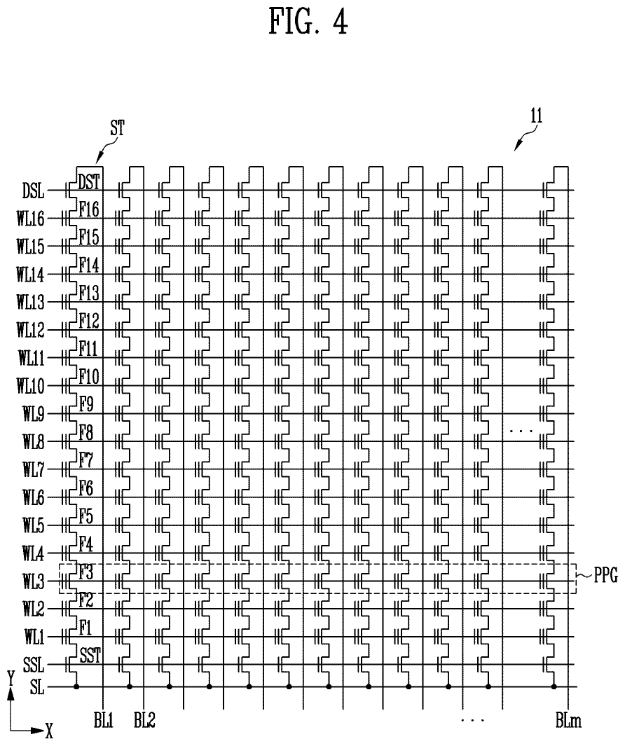

FIG. 4 is a diagram illustrating the memory block 11 of FIG. 2.

Referring to FIG. 4, a plurality of word lines WL1 to WL16 arranged parallel to each other between the first select line and the second select line may be coupled to the memory block 11. The first select line may be the source select line SSL, and the second select line may be the drain select line DSL. More specifically, the memory block 11 may include a plurality of memory strings ST coupled between the bit lines BL1 to BLm and the source line SL. The bit lines BL1 to BLm may be respectively coupled to the memory strings ST, and the source line SL may be commonly coupled to the memory strings ST. Since the memory strings ST may be configured to be identical to each other, the memory string ST coupled to the first bit line BL1 will be described in detail as an example.

The memory string ST may include a source select transistor SST, a plurality of memory cells F1 to F16, and a drain select transistor DST coupled in series between the source line SL and the first bit line BL1. One memory string ST may include at least one source select transistor SST and at least one drain select transistor DST, and memory cells F1 to F16 may be included more than the number shown in the drawings.

A source of the source select transistor SST may be coupled to the source line SL, and a drain of the drain select transistor DST may be coupled with the first bit line BL1. The memory cells F1 to F16 may be coupled in series between the source select transistor SST and the drain select transistor DST. Gates of source select transistors SST included in different memory strings ST may be coupled to the source select line SSL, gates of the drain select transistors DST may be coupled to the drain select line DSL, and gates of memory cells F1 to F16 may be coupled to the word lines WL1 to WL16. A group of memory cells coupled to the same word line among memory cells included in different memory strings ST may be referred to as a physical page PPG. Therefore, the memory block 11 may include as many physical pages PPG as the number of word lines WL1 to WL16.

One memory cell may store 1 bit of data and the method is commonly referred to as a single level cell SLC method. In such cases, one physical page PPG may store one logical page LPG data. One logical page LPG data may include data bits equal to the number of cells included in one physical page PPG. In addition, one memory cell may store two or more bits of data. The method is commonly referred to as a multi-level cell MLC method. In such cases, one physical page PPG may store two or more logical page LPG data.

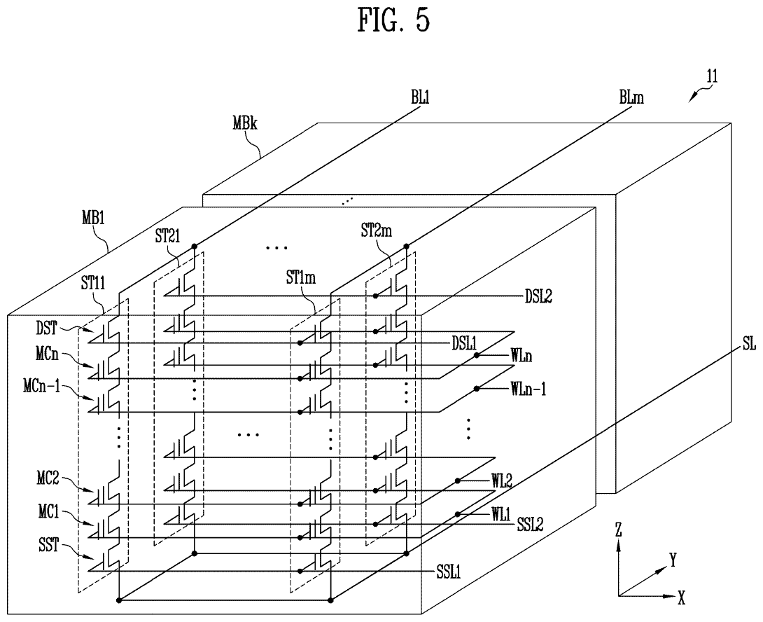

FIG. 5 is a diagram illustrating an embodiment of a three-dimensional memory block.

Referring to FIG. 5, the memory cell array 10 may include the memory blocks MB1 to MBk 11. The memory block 11 may include a plurality of memory strings ST11 to ST1m and ST21 to ST2m. Each of the memory strings ST11 to ST1m and ST21 to ST2m may extend in a vertical direction (in a Z direction). In the memory block 11, m memory strings may be arranged in a row direction (in a X direction). Although FIG. 5 illustrates two memory strings arranged in a column direction (in a Y direction) for convenience of description, three or more memory strings may be arranged in the column direction (in the Y direction).

Each of the memory strings ST11 to ST1m and ST21 to ST2m may include at least one source select transistor SST, first to nth memory cells MC1 to MCn, and at least one drain select transistor DST.

The source select transistor SST of each memory string ST may be coupled between the source line SL and the memory cells MC1 to MCn. The source select transistors SST of memory strings ST arranged in the same row may be coupled to the same source select line SSL. The source select transistors SST of the memory strings ST11 to ST1m arranged in the first row may be coupled to the first source select line SSL1. The source select transistors SST of the memory strings ST21 to ST2m arranged in the second row may be coupled to the second source select line SSL2. In another embodiment, the source select transistors SST of the memory strings ST11 to ST1m and ST21 to ST2m may be commonly coupled to one source select line.

The first to nth memory cells MC1 to MCn of each memory string ST may be coupled in series between the source select transistor SST and the drain select transistor DST. The gates of the first to nth memory cells MC1 to MCn may be coupled to the first to nth word lines WL1 to WLn, respectively.

In an embodiment, at least one of the first to nth memory cells MC1 to MCn may be used as a dummy memory cell. When a dummy memory cell is provided, the voltage or current of the memory string ST may be stably controlled. Accordingly, the reliability of data stored in the memory block 11 may be improved.

The drain select transistor DST of each memory string ST may be coupled between the bit line and the memory cells MC1 to MCn. The drain select transistors DST of the memory strings ST arranged in the row direction may be coupled to the drain select line extending in the row direction. The drain select transistors DST of the memory strings ST11 to ST1m in the first row may be coupled to the first drain select line DSL1. The drain select transistors DST of the memory strings ST21 to ST2m in the second row may be coupled to the second drain select line DSL.

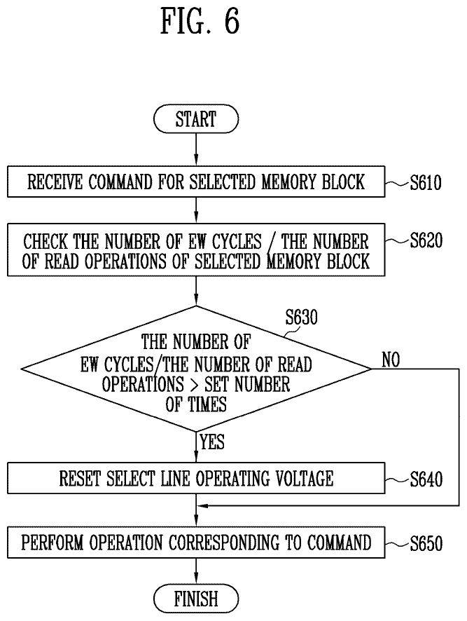

FIG. 6 is a flowchart illustrating a method of operating the semiconductor memory device 100 according to an embodiment of the present disclosure.

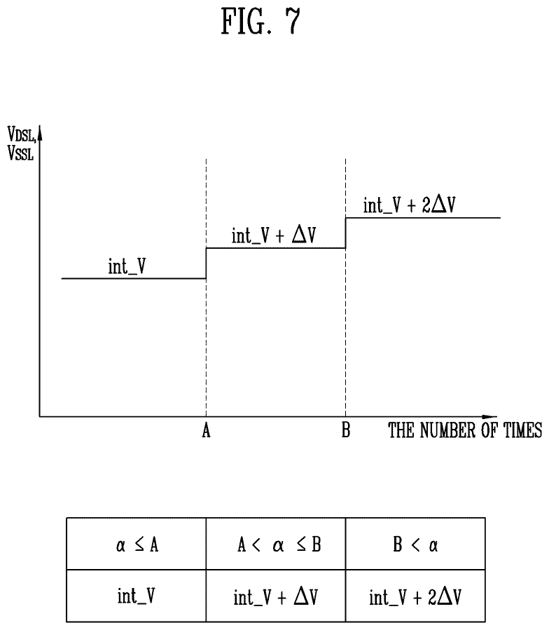

FIG. 7 is a diagram illustrating a method of setting the drain select line operating voltage or the source select line operating voltage based on the number of EW cycles or the number of read operations according to an embodiment of the present disclosure.

A method of operating the semiconductor memory device 100 according to an embodiment of the present disclosure will be described below with reference to FIGS. 2 to 7.

In operation S610, the semiconductor memory device 100 may receive the command CMD for the selected memory block (e.g., the memory block MB1). In an embodiment, the command CMD and the address ADD corresponding to the program, the read operation, or the erase operation may be received from the controller 1200 of FIG. 1 outside the semiconductor memory device 100.

In operation S620, the number of EW cycles or the number of read operations of the selected memory block MB1 may be checked.

For example, the counter 310 of the control logic 300 may output the first count signal E/W_Count or the second count signal Read_Count corresponding to the number of EW cycles or the number of read operations of the selected memory block MB1. The select line operating voltage setting circuit 320 of the control logic 300 may check the number of EW cycles or the number of read operations of the memory block MB1 selected based on the received first count signal E/W_Count or the second count signal Read_Count.

In operation S630, the number of EW cycles or the number of read operations and the number of settings of the selected memory block MB1 may be compared.

For example, the select line operating voltage setting circuit 320 may compare the number of EW cycles or the number of read operations of the selected memory block MB1 with the set number of times, and may determine whether the number of EW cycles or the number of read operations of the selected memory block MB1 is equal to or less than the set number of times, or whether the number of the EW cycles and the number of the read operations of the selected memory block MB1 exceeds the set number of times.

In the operation S630, when it is determined that the number of EW cycles or the number of read operations of the selected memory block MB1 exceeds the set number of times (if YES) in operation S640, the select line operating voltage setting circuit 320 may reset the drain select line operating voltage or the source select line operating voltage corresponding to the selected memory block MB1. For example, the select line operating voltage setting circuit 320 may set a new drain select line operating voltage or a source select line operating voltage that is increased by an offset voltage from the initial voltage level.

In the operation S630, when the number of EW cycles or the number of read operations of the selected memory block MB1 is equal to or less than the set number of times (if NO), the select line operating voltage setting circuit 320 may maintain the initially set drain select line operating voltage or source select line operating voltage without resetting the drain select line operating voltage or the source select line operating voltage.

Referring to FIG. 7, when the number of EW cycles or the number of read operations α of the selected memory block is equal to or less than a first set number of times (i.e., a first reference number) A, a drain select line operating voltage V_{DSL} or a source select line operating voltage V_{SSL} may be set to maintain an initial voltage level int_V.

In addition, when the number of EW cycles or the number of read operations α of the selected memory block exceeds the first set number of times A and is equal to or less than a second set number of times (i.e., a second reference number) B, the drain select line operating voltage V_{DSL} or the source select line operating voltage V_{SSL} may be reset by increasing by a first offset voltage ΔV from the initial voltage level int_V. In addition, when the number of EW cycles or the number of read operations α of the selected memory block exceeds the second set number of times B, the drain select line operating voltage V_{DSL} or the source select line operating voltage V_{SSL} may be reset by increasing the initial voltage level int_V by a second offset voltage 2ΔV.

In operation S650, the peripheral circuit 200 may perform an operation corresponding to the command CMD on the selected memory block MB1 under the control of the control logic 300, that is, the read operation, the program operation, or the erase operation.

The voltage generating circuit 210 may generate various operation voltages Vop used for the read operation, the program operation, or the erase operation in response to the operating signal OP_CMD, and may generate the operation voltages by adjusting the levels of the drain select line operating voltage and the source select line operating voltage based on the select line operating voltage information DSL_SSL_inf generated by the select line operating voltage setting circuit 320. The row decoder 220 may transmit the operating voltages Vop to the local lines LL coupled to the selected memory block MB1 in response to the control signals AD_signals, for example, the row decoder 220 may apply the drain select line operating voltage and the source select line operating voltage generated by the voltage generating circuit 210 to the drain select line and the source select line of the selected memory block MB1 in response to the row decoder control signal AD_signal.

According to an embodiment of the present disclosure described above, the drain select line operating voltage applied to the gates of the drain select transistors or the source select line operating voltage applying to the gates of source select transistors may be adjusted based on the number of EW cycles or the number of read operations of the selected memory block. Accordingly, even when the threshold voltage of the drain select transistors or the source select transistors increases due to an increase in the number of EW cycles or the number of read operations, the drain select transistor or the source select diode may operate stably by the adjusted drain select line operating voltage or the source select line operating voltage, so that the reliability of the semiconductor memory device 100 may be improved.

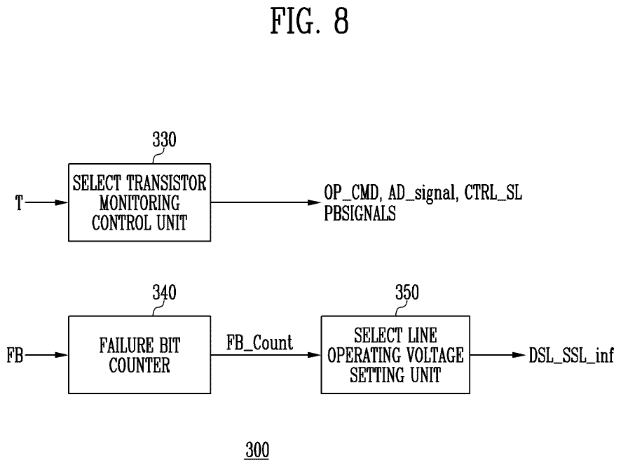

FIG. 8 is a diagram illustrating another embodiment of the control logic 300 of FIG. 2.

The control logic 300 may include a select transistor monitoring control circuit 330, a failure bit counter 340, and a select line operating voltage setting circuit 350.

The select transistor monitoring control circuit 330 may generate and output the operating signal OP_CMD, the control signals AD_signals, the source line control signal CTRL_SL, and the page buffer control signals PBSIGNALS for controlling the peripheral circuit 200 of FIG. 2 to perform the monitoring operation on the select transistors for each of the memory blocks MB1 to MBk 11 at regular intervals. For example, the select transistor monitoring control circuit 330 may generate and output the operating signal OP_CMD, the control signals AD_signals, the source line control signal CTRL_SL, and the page buffer control signals PBSIGNALS for controlling the peripheral circuit 200 of FIG. 2 to perform a monitoring operation in response to a time signal T activated at regular intervals.

The monitoring operation for the select transistors may be an operation of scanning the threshold voltage of the drain select transistors and the source select transistors included in the selected memory block to detect the drain select transistors or the source select transistors having a threshold voltage higher than a monitoring read voltage level. Among the drain select transistors and the source select transistors included in the selected memory block, the drain select transistors having a threshold voltage higher than the monitoring read voltage and the source select transistors may each be detected as one failure bit FB.

The failure bit counter 340 may receive the failure bits FB obtained as a result of the monitoring operation on the select transistors of the peripheral circuit 200, may count the received failure bits FB, and output a failure bit count signal FB_Count.

The select line operating voltage setting circuit 350 may receive the failure bit count signal FB_Count corresponding to each of the memory blocks MB1 to MBk 11 from the failure bit counter 340, and may set the drain select line operating voltage or the source select line operating voltage corresponding to each of the memory blocks MB1 to MB k 11 based on the received failure bit count signal FB_Count.

For example, the select line operating voltage setting circuit 350 may determine the number of failure bits of the memory block based on the received failure bit count signal FB_Count, and may set the drain select line operating voltage or the source select line operating voltage corresponding to the memory block by comparing the determined number of failure bits of the memory block with the set number of set bits. For example, the select line operating voltage setting circuit 350 may maintain the drain select line operating voltage or the source select line voltage of the initial voltage level when it is determined that the number of failure bits of the memory block is equal to or less than the first set number of bits, and may set a new drain select line operating voltage or a new source select line operating voltage that is increased by the first offset voltage at the initial voltage level when it is determined that the number of failure bits of the memory block exceeds the first set number of bits and is equal to or less than the second set number of bits that is greater than the first set number of bits. In addition, when it is determined that the number of failure bits of the memory block exceeds the second set number of bits greater than the first set number of bits, the select line operating voltage setting circuit 350 may set a new drain select line operating voltage or a source select line operating voltage that is increased by the second offset voltage greater than the first offset voltage at the initial voltage level.

The select line operating voltage setting circuit 350 may perform the operation of setting the drain select line operating voltage or the source select line operating voltage described above for each of the memory blocks MB1 to MBk 11.

The select line operating voltage setting circuit 350 may output the select line operating voltage information DSL_SSL_inf including information on the level of the set drain select line operating voltage or the level of the set source select line operating voltage. The select line operating voltage information DSL_SSL_inf may be transmitted to the voltage generating circuit 210 of FIG. 2, and the voltage generating circuit 210 may adjust the levels of the drain select line operating voltage and the source select line operating voltage based on the select line operating voltage data DSL_SSL_inf.

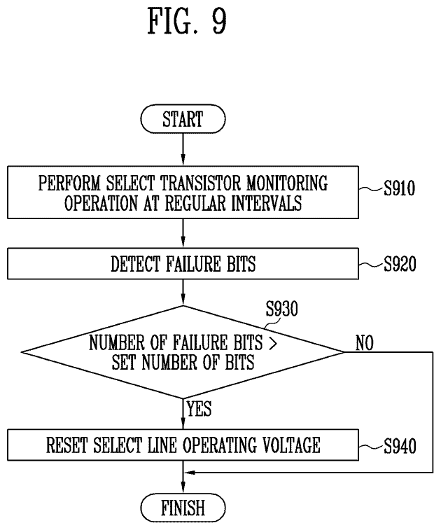

FIG. 9 is a flowchart illustrating a method of operating the semiconductor memory device 100 according to another embodiment of the present disclosure.

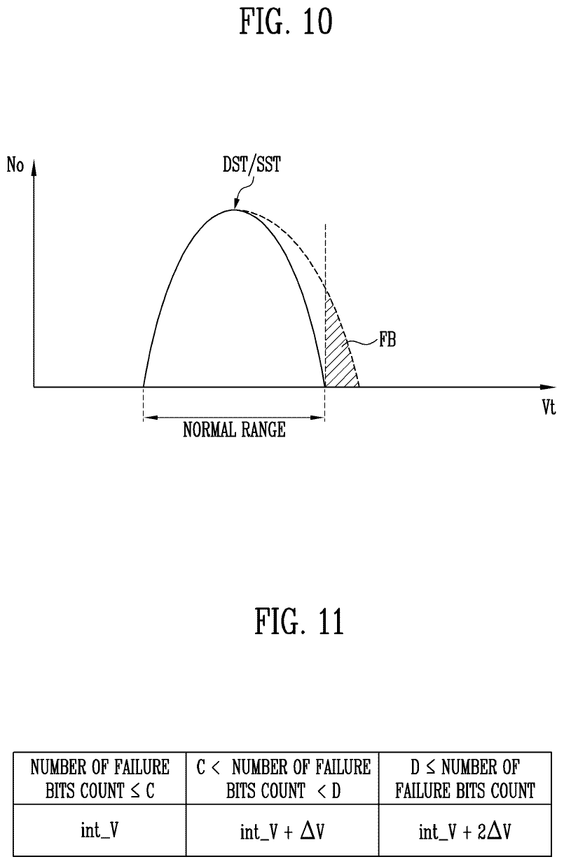

FIG. 10 is a threshold voltage distribution diagram for illustrating a select transistor monitoring operation method according to an embodiment of the present disclosure.

FIG. 11 is a diagram illustrating a method of setting the drain select line operating voltage or the source select line operating voltage based on the number of failure bits according to an embodiment of the present disclosure.

A method of operating the semiconductor memory device 100 according to another embodiment of the present disclosure will be described below with reference to FIGS. 2 to 5 and FIGS. 8 to 11.

In operation S910, the semiconductor memory device 100 may perform the select transistor monitoring operation on each of the memory blocks MB1 to MBk 11 at the regular intervals.

For example, the select transistor monitoring control circuit 330 may generate and output the operation signal OP_CMD, the control signals AD_signals, the source line control signal CTRL_SL, and the page buffer control signals PBSIGNALS for controlling the peripheral circuit 200 of FIG. 2 to perform the monitoring operation in response to the time signal T activated at the regular intervals.

The peripheral circuit 200 may perform the select transistor monitoring operation on each of the memory blocks MB1 to MBk 11 in response to the operation signal OP_CMD, the control signals AD_signals, the source line control signal CTRL_SL, and the page buffer control signals PBSIGNALS.

For example, the voltage generating circuit 210 may generate the monitoring read voltage to apply to the selected drain select line or the selected source select line, and the pass voltage to apply to the unselected drain select line, the unselected source select line and the word lines.

The row decoder 220 may apply the monitoring read voltage to the selected drain select line or the selected source select line, and may apply the pass voltage to the remaining unselected drain select line, the unselected source select line and the word lines.

The threshold voltage change amount of the drain select transistors and the source select transistors may be relatively small for a certain period of time after the semiconductor memory device 100 is produced, the activation of the time signal T may be prevented in the set initial period, so that the select transistor monitoring may be skipped in the set initial period, and the select transistor monitoring operation may be performed at regular intervals after the initial period.

In operation S920, each of the page buffers PB1 to PBm 231 may detect the failure bit FB. For example, each of the page buffers PB1 to PBm 231 may sense a voltage or current of the bit lines BL1 to BLm during the monitoring operation on the select transistors to detect the drain select transistor or the source select transistors having a threshold voltage higher than the monitoring read voltage to generate and output the failure bit FB. Some drain select transistors or source select transistors having a threshold voltage that exceeds a normal range among the threshold voltage distributions of the drain select transistors DST and the source select transistors SST as shown in FIG. 10 may be detected as the failure bit FB.

The failure bit counter 340 may receive the failure bits FB obtained as a result of the monitoring operation on the select transistors of the peripheral circuit 200, and may count the received failure bits FB.

In operation S930, the select line operating voltage setting circuit 350 may compare the counted number of failure bits with the set number of bits.

For example, the select line operating voltage setting circuit 350 may compare the number of failure bits of each of the memory blocks MB1 to MBk 11 with the set number of bits, and may determine whether the number of failure bits of each the memory blocks MB1 to MBk 11 is equal to or less than the set number of bits or exceeds the number of bits.

In the operation S930, when it is determined that the number of failure bits of the memory block exceeds the set number of bits (if YES), in operation S940, the select line operating voltage setting circuit 350 may reset the drain select line operating voltage or the source select line operating voltage corresponding to the memory block. For example, the select line operating voltage setting circuit 350 may set a new drain select line operating voltage or a source select line operating voltage that is increased by the offset voltage from the initial voltage level.

In the operation S930, when the number of failure bits of the memory block is equal to or smaller than the set number of bits (if NO), the select line operating voltage setting circuit 350 may maintain the initially set drain select line operating voltage or source select line operating voltage without resetting the drain select line operating voltage or the source select line operating voltage corresponding to the memory block.

Referring to FIG. 11, when the number of failure bits FB count of the memory block is equal to or less than a first set number of bits (i.e., a first reference number) C, the drain select line operating voltage or the source select line operating voltage may be set to maintain the initial voltage level int_V.

In addition, when the number of failure bits FB count of the memory block exceeds the first set number of bits C and is equal to or less than a second set number of bits (i.e., a first reference number) D, the drain select line operating voltage or the source select line operating voltage may be reset by increasing the first offset voltage ΔV from the initial voltage level int_V. In addition, when the number of failure bits FB count of the memory block exceeds the second set number of bits D, the drain select line operating voltage V_{DSL} or the source select line operating voltage may be reset by increasing by the second offset voltage 2ΔV from the initial voltage level int_V.

The operation of setting the drain select line operating voltage or the source select line operating voltage corresponding to the memory block may be sequentially performed for each of the memory blocks MB1 to MBk 11.

According to another embodiment of the present disclosure, the drain select line operating voltage applied to the gates of the drain select transistors or the source select line operating voltage that is applied to the gates of the source select transistors may be adjusted based on the number of failure bits of the memory block. Accordingly, the drain select transistors or the source select transistors may operate stably, so that the reliability of the semiconductor memory device 100 may be improved.

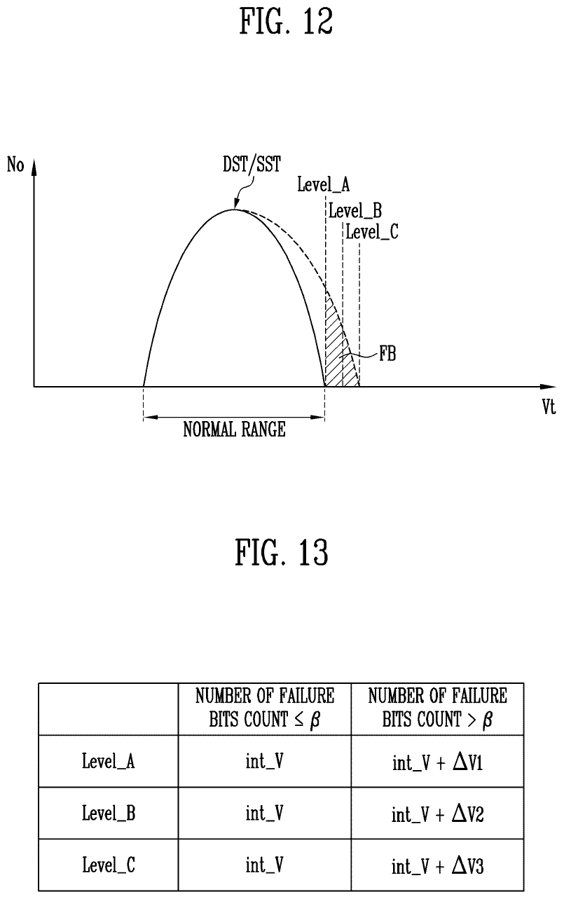

FIG. 12 is a threshold voltage distribution diagram illustrating another select transistor monitoring operation method according to an embodiment of the present disclosure.

FIG. 13 is a diagram illustrating a method of setting the drain select line operating voltage or the source select line operating voltage based on the number of failure bits according to an embodiment of the present disclosure.

Referring to FIGS. 2, 8, 12, and 13, the peripheral circuit 200 may sequentially perform the threshold voltage monitoring operation of the select transistors using a plurality of monitoring read voltages, for example, a first monitoring read voltage Level_A, a second monitoring read voltage Level_B greater than the first monitoring read voltage Level_A, and a third monitoring read voltage Level_C greater than the second monitoring read voltage Level_B.

For example, in a threshold voltage monitoring operation of the select transistors using the first monitoring read voltage Level_A, the voltage generating circuit 210 may generate the first monitoring read voltage Level_A for applying to the selected drain select line or the selected source select line and a pass voltage for applying to the unselected drain select line, the unselected source select line, and the word lines.

The row decoder 220 may apply the first monitoring read voltage Level_A to the selected drain select line or the selected source select line, and may apply the pass voltage to the remaining unselected drain select line, the unselected source select line, and the word lines.

Each of the page buffers PB1 to PBm 231 may detect the failure bit FB by sensing the voltage or current of the bit lines BL1 to BLm during the threshold voltage monitoring operation of the select transistors using the first monitoring read voltage Level_A.

Subsequently, in the threshold voltage monitoring operation of the select transistors using the second monitoring read voltage Level_B, the voltage generating circuit 210 may generate the second monitoring read voltage Level_B, and the row decoder 220 may apply the second monitoring read voltage Level_B to the selected drain select line or the selected source select line. Each of the page buffers PB1 to PBm 231 may sense the voltage or current of the bit lines BL1 to BLm during the threshold voltage monitoring operation of the select transistors using the second monitoring read voltage Level_B to detect the failure bit FB.

Subsequently, in the threshold voltage monitoring operation of the select transistors using the third monitoring read voltage Level_C, the voltage generating circuit 210 may generate the third monitoring read voltage Level_ C, and the row decoder 220 may apply the third monitoring read voltage Level_C to the selected drain select line or the selected source select line. Each of the page buffers PB1 to PBm 231 may detect the failure bit FB by sensing the voltage or current of the bit lines BL1 to BLm during the threshold voltage monitoring operation of the select transistors using the third monitoring read voltage Level_C.

The failure bit counter 340 may count the number of failure bits FB received during the threshold voltage monitoring operation of the select transistors using the first monitoring read voltage Level_A, the number of failure bits FB received during the threshold voltage monitoring operation performed on the select transistors by using the second monitoring read voltage Level_B, and the number of failure bits FB received during the threshold voltage monitoring performed on the selected transistors by using the third monitoring read voltage Level_C, respectively.

The select line operating voltage setting circuit 350 may maintain the drain select line operating voltage or the source select line operating voltage at the initial voltage level int_V when the number of failure bits FB count received and counted during the threshold voltage monitoring operation of the select transistors using the first monitoring read voltage Level_A is equal to or less than a set number of bits (i.e., a reference number) β. On the other hand, when the number of failure bits FB count received and counted during the threshold voltage monitoring operation of the select transistors using the first monitoring read voltage Level_A exceeds the set number of bits β, the drain select line operating voltage or the source select line operating voltage is raised by a first voltage ΔV1 from the initial voltage level int_V to set a new drain select line operating voltage or source select line operating voltage.

In addition, the select line operating voltage setting circuit 350 may maintain the drain select line operating voltage or the source select line operating voltage at the initial voltage level int_V when the number of failure bits FB count received and counted during the threshold voltage monitoring operation of the select transistors using the second monitoring read voltage Level_B is equal to or less than the set number of bits β. On the other hand, when the number of failure bits FB count received and counted during the threshold voltage monitoring operation of the select transistors using the second monitoring read voltage Level_B exceeds the set number of bits β, the drain select line operating voltage or the source select line operating voltage is raised by a second voltage ΔV2 greater than the first voltage ΔV1 from the initial voltage level int_V to set a new drain select line operating voltage or source select line operating voltage.

In addition, the select line operating voltage setting circuit 350 may maintain the drain select line operating voltage or the source select line operating voltage at the initial voltage level int_V when the number of failure bits FB count received and counted during the threshold voltage monitoring operation of the select transistors using the third monitoring read voltage Level_C is equal to or less than the set number of bits β. On the other hand, when the number of failure bits FB count received and counted during the threshold voltage monitoring operation of the select transistors using the third monitoring read voltage Level_C exceeds the set number of bits β, the drain select line operating voltage or the source select line operating voltage is raised by a third voltage ΔV3 greater than the second voltage ΔV2 from the initial voltage level int_V to set a new drain select line operating voltage or source select line operating voltage.

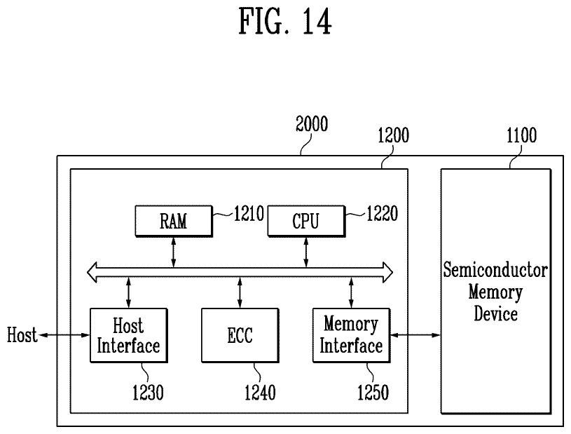

FIG. 14 is a block diagram illustrating a configuration of a storage device 2000 according to another embodiment of the present disclosure.

Referring to FIG. 14, the storage device 2000 may include the semiconductor memory device 1100 and the controller 1200.

The semiconductor memory device 1100 may be used to store data information having various data types such as text, graphics, software code, or the like. The semiconductor memory device 1100 may be the same as the semiconductor memory device described with reference to FIG. 2. The structure and operation method of the semiconductor memory device 1100 are the same as those described above, and thus a detailed description thereof will be omitted.

The controller 1200 may be coupled to a host and the memory device 1100, and may be configured to access the memory device 1100 according to a request from the host. For example, the controller 1200 may be configured to control read, write, erase, and background operations of the memory device 1100.

The controller 1200 may include a Random Access Memory (RAM) 1210, a Central Processing Unit (CPU) 1220, a Host Interface (Host Interface) 1230, an ECC circuit (ECC) 1240, a memory interface (Memory Interface) 1250, or the like.

The RAM 1210 may be used as an operation memory of the CPU 1220, a cache memory between the memory device 1100 and the host, a buffer memory between the memory device 1100 and the host, or the like. For reference, the RAM 1210 may be replaced with a Static Random Access Memory (SRAM), a Read Only Memory (ROM), or the like.

The CPU 1220 may be configured to control the overall operation of the controller 1200. For example, the CPU 1220 may be configured to operate firmware such as a Flash Translation Layer (FTL) stored in the RAM 1210.

The host interface 1230 may be configured to perform interfacing with the host. For example, the controller 1200 may communicate with the host through at least one of various communication standards or interfaces, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA protocol, a Parallel-ATA Protocol, a Small Computer System Interface (SCSI) protocol, an Enhanced Small Disk Interface (ESDI) protocol, an Integrated Drive Electronics (IDE) protocol, and a private protocol.

The ECC circuit 1240 may be configured to detect and correct an error included in data read from the memory device 1100 using an error correction code.

The memory interface 1250 may be configured to perform interfacing with the memory device 1100. For example, the memory interface 1250 may include a NAND interface or a NOR interface.

For reference, the controller 1200 may further include a buffer memory (not shown) for temporarily storing data. The buffer memory may be used to temporarily store data transmitted to the outside through the host interface 1230 or temporarily store data transmitted from the memory device 1100 through the memory interface 1250. In addition, the controller 1200 may further include the ROM for storing code data for interfacing with the host.

As described above, since the storage device 2000 includes the semiconductor memory device 1100 having an improved degree of integration and improved characteristics, the degree of integration and characteristics of the storage device 2000 may also be improved.

According to embodiments of the present disclosure, a semiconductor memory device may adjust an operating voltage by predicting a change in a threshold voltage of a selected transistor, so that the reliability of the semiconductor memory device may be improved.

While the embodiments of the present disclosure have been illustrated and described with respect to specific embodiments and drawings, the disclosed embodiments are not intended to be restrictive. Further, it is noted that the embodiments may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A semiconductor memory device comprising:
a memory cell array including a plurality of memory blocks;
a peripheral circuit configured to perform a program operation, a read operation, or an erase operation on the plurality of memory blocks; and
a control logic configured to
set a level of a drain select line operating voltage or a level of a source select line operating voltage corresponding to each memory block based on a number of erase-write (EW) cycles or a number of read operations for each memory block, and
control the peripheral circuit to perform the program operation, the read operation, or the erase operation based on the set drain select line operating voltage or the set source select line operating voltage.

2. The semiconductor memory device of claim 1,
wherein the control logic includes:
a counter configured to count the number of EW cycles or the number of read operations for each memory block; and
a select line operating voltage setting circuit configured to compare the number of EW cycles or the number of read operations with a reference number, and set the level of the drain select line operating voltage or the level of the source select line operating voltage based on a comparison result.

3. The semiconductor memory device of claim 2, wherein the select line operating voltage setting circuit is configured to set the level of the drain select line operating voltage or the level of the source select line operating voltage to an initial voltage level when the number of EW cycles or the number of read operations is equal to or less than the reference number.

4. The semiconductor memory device of claim 3, wherein the select line operating voltage setting circuit is configured to set the level of the drain select line operating voltage or the level of the source select line operating voltage to a level increased by an offset voltage from the initial voltage level when the number of EW cycles or the number of read operations exceeds the reference number.

5. The semiconductor memory device of claim 2,
wherein the select line operating voltage setting circuit is configured to set the level of the drain select line operating voltage or the level of the source select line operating voltage to an initial voltage level when the number of EW cycles or the number of read operations is equal to or less than a first reference number, and
wherein the select line operating voltage setting circuit is configured to set the level of the drain select line operating voltage or the level of the source select line operating voltage to a first level increased by a first offset voltage from the initial voltage level when the number of EW cycles or the number of read operations exceeds the first reference number and is equal to or less than a second reference number which is greater than the first reference number.

6. The semiconductor memory device of claim 5, wherein the select line operating voltage setting circuit sets the level of the drain select line operating voltage or the level of the source select line operating voltage to a second level increased by a second offset voltage when the number of EW cycles or the number of read operations exceeds the second reference number, the second offset voltage being greater than the first offset voltage from the initial voltage level.

7. A method of operating a semiconductor memory device, the method comprising:
receiving a command corresponding to a selected memory block among a plurality of memory blocks;
checking a number of erase-write (EW) cycles or a number of read operations of the selected memory block;
setting a drain select line operating voltage or a source select line operating voltage of the selected memory block based on the number of EW cycles or the number of read operations of the selected memory blocks; and
performing a program operation, a read operation, or an erase operation corresponding to the command by using the set drain select line operating voltage or source select line operating voltage.

8. The method of claim 7, wherein setting the drain select line operating voltage or the source select line operating voltage comprises:
comparing the number of EW cycles or the number of read operations with a reference number;
setting a level of the drain select line operating voltage or the source select line operating voltage to an initial voltage level according to a comparison result of the number of EW cycles or the number of read operations being equal to or less than the reference number; and
setting the level of the drain select line operating voltage or the level of the source select line operating voltage to a first level increased by an offset voltage from the initial voltage level according to a comparison result of the number of EW cycles or the number of read operations exceeding the reference number.

9. The method of claim 7, wherein setting the drain select line operating voltage or source select line operating voltage comprises:
comparing the number of EW cycles or the number of read operations with a first reference number and a second reference number which is greater than the first reference number;
setting the level of the drain select line operating voltage or the level of the source select line operating voltage to a first level increased by a first offset voltage from the initial voltage level according to a comparison result of the number of EW cycles or the number of read operations exceeding the first reference number and is equal to or less than the second reference number; and
setting the level of the drain select line operating voltage or the level of the source select line operating voltage to a second level increased by a second offset voltage from the initial voltage level according to a comparison result of the number of EW cycles or the number of read operations exceeding the second reference number, the second offset voltage being greater than the first offset voltage.

10. A semiconductor memory device comprising:
a memory cell array including a plurality of memory blocks;
a peripheral circuit configured to perform a program operation, a read operation, an erase operation, or a select transistor monitoring operation on the plurality of memory blocks; and
a control logic configured to control the peripheral circuit to
periodically perform the select transistor monitoring operation on each memory block, and
set a level of a drain select line operating voltage or a level of a source select line operating voltage used for the program operation, the read operation, or the erase operation based on a number of failure bits corresponding to each memory block, obtained as a result of the select transistor monitoring operation.

11. The semiconductor memory device of claim 10,
wherein the peripheral circuit is configured to:
periodically perform the select transistor monitoring operation on each of the plurality of memory blocks; and
detect select transistors having a threshold voltage greater than a monitoring read voltage among drain select transistors and source select transistors included in a selected memory block when performing the select transistor monitoring operation to output failure bit information corresponding to each of the detected select transistors.

12. The semiconductor memory device of claim 11,
wherein the control logic comprises:
a failure bit counter configured to receive the failure bit information from the peripheral circuit to count the number of failure bits of the selected memory block; and
a select line operating voltage setting circuit configured to set a level of the drain select line operating voltage or the source select line operating voltage of the selected memory block based on the number of failure bits.

13. The semiconductor memory device of claim 12, wherein the select line operating voltage setting circuit is configured to set the level of the drain select line operating voltage or the level of the source select line operating voltage to an initial voltage level when the number of failure bits is equal to or less than a reference number.

14. The semiconductor memory device of claim 13, wherein the select line operating voltage setting circuit is configured to set the level of the drain select line operating voltage or the level of the source select line operating voltage to a first level increased by an offset voltage from the initial voltage level when the number of failure bits exceeds the reference number.

15. The semiconductor memory device of claim 12, wherein the select line operating voltage setting circuit is configured to set the level of the drain select line operating voltage or the level of the source select line operating voltage to an initial voltage level when the number of failure bits is equal to or less than a first reference number.

16. The semiconductor memory device of claim 15, wherein the select line operating voltage setting circuit is configured to set the level of the drain select line operating voltage or the level of the source select line operating voltage to a first level increased by a first offset voltage from the initial voltage level when the number of failure bits exceeds the first reference number and is equal to or less than a second reference number which is greater than the first reference number.

17. The semiconductor memory device of claim 16, wherein the select line operating voltage is configured to set the level of the drain select line operating voltage or the level of the source select line operating voltage to a second level increased by a second offset voltage greater than the first offset voltage from the initial voltage level when the number of failure bits exceeds the second reference number.

18. The semiconductor memory device of claim 10,
wherein the select transistor monitoring operation includes a first monitoring operation performed based on a first monitoring read voltage, a second monitoring operation performed based on a second monitoring read voltage greater than the first monitoring read voltage, and a third monitoring operation performed based on a third monitoring read voltage greater that the second monitoring read voltage, and
wherein the peripheral circuit is configured to:
detect, during the first monitoring operation, select transistors having a threshold voltage greater than the first monitoring read voltage among the drain select transistors and the source select transistors included in the selected memory block to output failure bit information for the first monitoring operation;
detect, during the second monitoring operation, select transistors having a threshold voltage greater than the second monitoring read voltage among the drain select transistors and the source select transistors included in the selected memory block to output failure bit information for the second monitoring operation; and
detect, during the third monitoring operation, select transistors having a threshold voltage greater than the third monitoring read voltage among the drain select transistors and the source select transistors included in the selected memory block to output failure bit information for the third monitoring operation.

19. The semiconductor memory device of claim 18, wherein the control logic comprises:
a failure bit counter configured to receive the failure bit information from the peripheral circuit to count each number of failure bits corresponding to each of the first monitoring operation, the second monitoring operation, and the third monitoring operation; and
a select line operating voltage setting circuit configured to set the level of the drain select line operating voltage or the level of the source select line operating voltage of the selected memory block based on the number of the failure bits corresponding to the first monitoring operation, the number of the failure bits corresponding to the second monitoring operation, and the number of the failure bits corresponding to the third monitoring operation.

20. The semiconductor memory device of claim 19, wherein the select line operating voltage setting circuit is configured to:
set the level of the drain select line operating voltage or the level of the source select line operating voltage to an initial voltage level when the number of the failure bits corresponding to the first monitoring operation is equal to or less than the reference number; and
set the level of the drain select line operating voltage or the level of the source select line operating voltage to a first level increased by a first offset voltage from the initial voltage level when the number of failure bits corresponding to the first monitoring operation exceeds a reference number.

21. The semiconductor memory device of claim 20, wherein the select line operating voltage setting circuit is configured to:
set the level of the drain select line operating voltage or the level of the source select line operating voltage to the initial voltage level when the number of failure bits corresponding to the second monitoring operation is equal to or less than the reference number; and
set the level of the drain select line operating voltage or the level of the source select line operating voltage to a second level increased by a second offset voltage from the initial voltage level when the number of failure bits corresponding to the second monitoring operation exceeds the reference number, the second offset voltage being greater than the first offset voltage.

22. The semiconductor memory device of claim 21, wherein the select line operating voltage setting circuit is configured to:
set the level of the drain select line operating voltage or the level of the source select line operating voltage to the initial voltage level when the number of failure bits corresponding to the third monitoring operation is equal to or less than the reference number; and
set the level of the drain select line operating voltage or the level of the source select line operating voltage to a third level increased by a third offset voltage from the initial voltage level when the number of failure bits corresponding to the third monitoring operation exceeds the reference number, the third offset voltage being greater than the second offset voltage.

23. The semiconductor memory device of claim 10,
wherein the control logic includes a select transistor monitoring control circuit configured to control the peripheral circuit to periodically perform the select transistor monitoring operation, and
wherein the select transistor monitoring control circuit is configured to skip the select transistor monitoring operation during a set initial period, and control the peripheral circuit to periodically perform the select transistor monitoring operation after the initial period.

24. A method of operating a semiconductor memory device, the method comprising:
performing a first select transistor monitoring operation on a selected memory block among a plurality of memory blocks;
detecting, based on a result of the first select transistor monitoring operation, a number of select transistors having a threshold voltage greater than a first monitoring read voltage, among drain select transistors and source select transistors included in the selected memory block to count a first number of failure bits; and
setting a drain select line operating voltage or a source select line operating voltage corresponding to the selected memory block based on the counted first number of failure bits.

25. The method of claim 24, further comprising, setting, according to a determination that the counted first number of failure bits is equal to or less than a reference number, a level of the drain select line operating voltage or a level of the source select line operating voltage to an initial voltage level.

26. The method of claim 25, further comprising, setting, according to a determination that the counted first number of failure bits exceeds the reference number, the level of the drain select line operating voltage or the level of the source select line operating voltage to a level increased by an offset voltage from the initial voltage level.

27. The method of claim 24, further comprising:
performing a second select transistor monitoring operation on the selected memory block;
detecting a number of select transistors having a threshold voltage greater than a second monitoring read voltage, among the drain select transistors and the source select transistors based on a result of the second select transistor monitoring operation to count a second number of failure bits, the second monitoring read voltage being greater than the first monitoring read voltage; and
setting the drain select line operating voltage or the source select line operating voltage corresponding to the selected memory block based on the counted second number of failure bits.
